(19) United States
(12) Patent Application Publication
(10) Pub. No.: US 2015/0101846 A1
(43) Pub. Date: Apr. 16, 2015

(54) PRINTED CIRCUIT BOARD AND METHOD OF MANUFACTURING THE SAME

(71) Applicant: Samsung Electro-Mechanics Co., Ltd., Suwon-si (KR)

(72) Inventors: Ho Shik Kang, Suwon-si (KR); Jong Tae Park, Suwon-si (KR)

(73) Assignee: SAMSUNG ELECTRO-MECHANICS CO., LTD., Suwon-si (KR)

(21) Appl. No.: 14/160,209

(22) Filed: Jan. 21, 2014

(30) Foreign Application Priority Data
Oct. 14, 2013 (KR) 10-2013-0122127

(51) Int. Cl. H05K 1/02; H05K 3/00; H05K 3/46

(52) U.S. Cl. CPC H05K 1/02; H05K 3/4644; H05K 3/0091; H05K 3/007
USPC 174/250; 264/104

(57) ABSTRACT

Disclosed herein are a printed circuit board and a method of manufacturing the same. The printed circuit board according to the present invention may include: a plurality of circuit layers; and a plurality of insulating layers interposed between the plurality of circuit layers, wherein two adjacent insulating layers of the plurality of insulating layers have different thicknesses.

### CROSS REFERENCE TO RELATED APPLICATION

This application claims the benefit of Korean Patent Application No. 10-2013-0122127, filed on Oct. 14, 2013, entitled “Printed Circuit Board and Method of Manufacturing the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

In accordance with the recent trend toward miniaturization and multi-function in electronic components, highly integrated thin-type products manufactured by applying fine pattern and a stacked structure to an existing printed circuit board to maximize radiation properties have been increasingly demanded. In this situation, coreless products using detached carriers are capable of having a thin thickness, decreased resistance, and high performance and being manufactured be an odd number of layers, such that the demand thereof has been increased.

However, in the coreless product using the detached carrier, a warpage is generally generated during a manufacturing process thereof, thereby causing problems such as damage and rolling in a substrate during the manufacturing process.

The printed circuit board has vias formed therein in order to connect an electrical signal between circuit layers, wherein the vias and insulating layers are subject to a polishing process so that each height or each shape of the vias and the insulating layers satisfies a designed intent to thereby manufacture the product. In the process of manufacturing the substrate, including the polishing process, among the coreless products using the detached carriers, since the substrate has a vertically symmetrical structure before performing a detaching process, a warpage is hardly generated. However, the structure is changed into a vertically asymmetrical structure by performing the detaching process, and the warpage is generated during a copper etching process, causing various problems.

### PRIOR ART DOCUMENT

### Patent Document

(Patent Document 1) Korean Patent Laid-Open Publication No. 2012-0047826

### SUMMARY OF THE INVENTION

The present invention has been made in an effort to provide a printed circuit board capable of having different thicknesses of insulating layers by performing a polishing process to thereby prevent a warpage, and a method of manufacturing the same.

According to a preferred embodiment of the present invention, there is provided a printed circuit board including: a plurality of circuit layers; and a plurality of insulating layers interposed between the plurality of circuit layers, wherein two adjacent insulating layers of the plurality of insulating layers have different thicknesses.

Two adjacent insulating layers may have a glass cloth.

The printed circuit board may further include: vias electrically connecting between the plurality of circuit layers while penetrating through the insulating layers.

According to another preferred embodiment of the present invention, there is provided a method of manufacturing a printed circuit board, the method including: preparing a carrier substrate; forming first circuit layers on both surfaces of the carrier substrate; forming a first via on the first circuit layer; forming a first insulating layer so as to enclose the first circuit layer and the first via; polishing the first insulating layer; forming a second circuit layer at a position corresponding to the first via; forming a second via on the second circuit layer; forming a second insulating layer so as to enclose the second circuit layer and the second via; polishing the second insulating layer so as to have a thickness thinner than that of the first insulating layer; and separating the first insulating layer from the carrier substrate.

The forming of the first via may include: forming a resist on the first circuit layer, the resist having an opening part at a position corresponding to the first via; filling the opening part with a metal to form the first via; and removing the resist.

The forming of the second via may include: forming a resist on the second circuit layer, the resist having an opening part at a position corresponding to the second via; filling the opening part with a metal to form the second via; and removing the resist.

The method may further include: forming a third circuit layer at a position corresponding to the second via after the polishing of the second insulating layer.

The method may further include: attaching a protective film onto the carrier substrate in the preparing of the carrier substrate; and removing the protective film after the separating of the first insulating layer from the carrier substrate.

The first and second insulating layers may have a glass cloth.

The glass cloth of first and second insulating layers may be partially polished in the polishing of the first insulating layer and the second insulating layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a printed circuit board according to a preferred embodiment of the present invention; and

FIGS. 2 to 14 are process flow charts showing a method of manufacturing a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

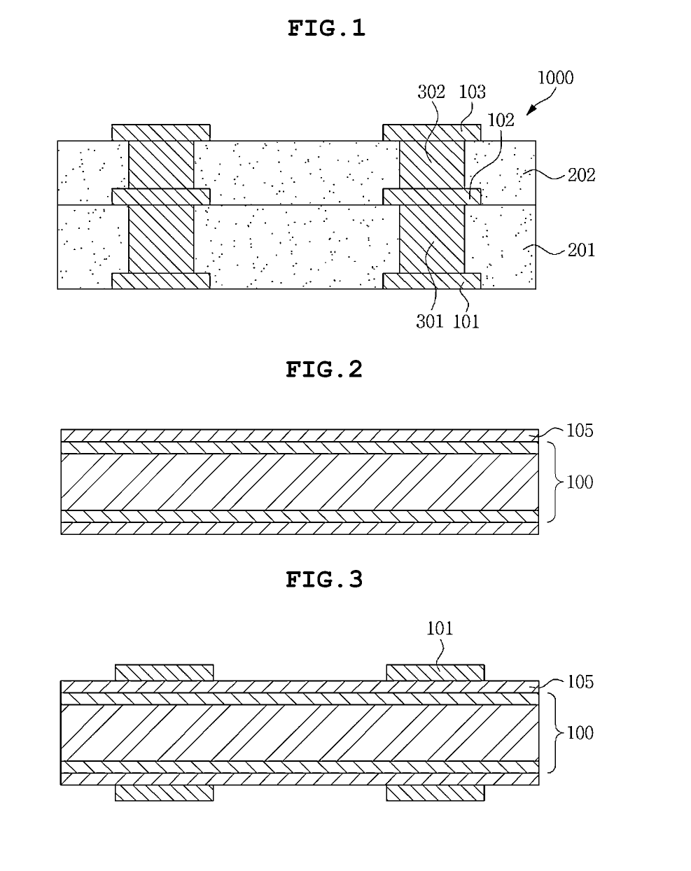

FIG. 1 is a cross-sectional view of a printed circuit board according to a preferred embodiment of the present invention.

As shown in FIG. 1, the printed circuit board 1000 may include: a plurality of circuit layers 101, 102, and 103; and a plurality of insulating layers 201 and 202 interposed between the plurality of circuit layers 101, 102, and 103, wherein two adjacent insulating layers 201 and 202 of the plurality of insulating layers 201 and 202 have different thicknesses.

Here, a thickness of a lower insulating layer 201 of two adjacent insulating layers may be the same as or larger than that of an upper insulating layer 202.

In addition, although not shown, a build-up layer may be further formed on the upper insulating layer 202.

As the insulating layer, a resin insulating layer may be used. As the resin insulating layer, a thermosetting resin such as an epoxy resin, a thermoplastic resin such as polyimide, or a resin having a reinforcing material such as a glass fiber or an inorganic filler impregnated thereinto, for example, a prepreg, may be used.

As the circuit layer, any material may be applied without limitation as long as a material is used as a conductive metal for a circuit in a circuit board field, and may be typically made of copper in the case of a printed circuit board.

The exposed circuit layer may further include a surface treatment layer (not-shown) formed thereon as needed.

The surface treatment layer is not specifically limited as long as the surface treatment layer is known in the art, and may be formed by, for example, an electro gold plating, an immersion gold plating, an organic solderability preservative (OSP) or an immersion tin plating, an immersion silver plating, an electroless nickel and immersion gold (ENIG), a direct immersion gold (DIG) plating, a hot air solder leveling (HASL), or the like.

In addition, vias 301 and 302 electrically connecting the plurality of circuit layers 101, 102, and 103 may be formed.

Method of Manufacturing Printed Circuit Board

FIGS. 2 to 14 are process flow charts showing a method of manufacturing a printed circuit board according to another preferred embodiment of the present invention.

As shown in FIG. 2, a carrier substrate 100 having protective films 105 formed on both surfaces thereof is prepared.

As shown in FIG. 3, a first circuit layer 101 may be formed on both surfaces of the protective film 105.

Here, the circuit layer may be formed by using an etching process or a plating filling method, and any known method of forming a circuit in the art may be performed.

In addition, as a material for forming the circuit layer, any material may be applied without limitation as long as the material is used as a conductive metal for a circuit in a circuit board field, and may be typically made of copper in the case of a printed circuit board.

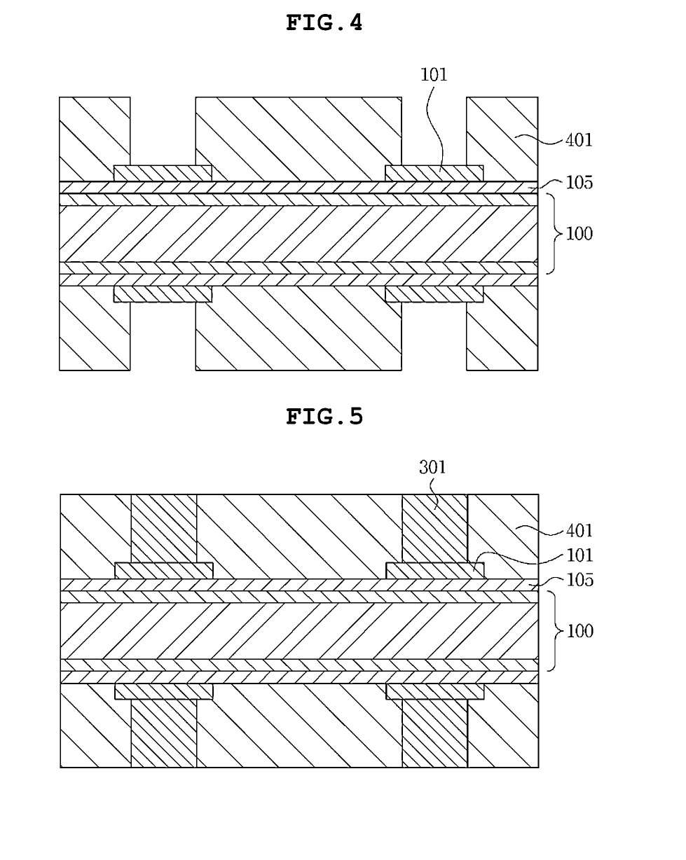

As shown in FIG. 4, a resist 401 for forming vias, having an opening part may be formed at a position corresponding to the first circuit layer 101.

As shown in FIG. 5, a first via 301 may be formed by filling the opening part with a metal.

It is general that a conductive metal is used as the metal for filling.

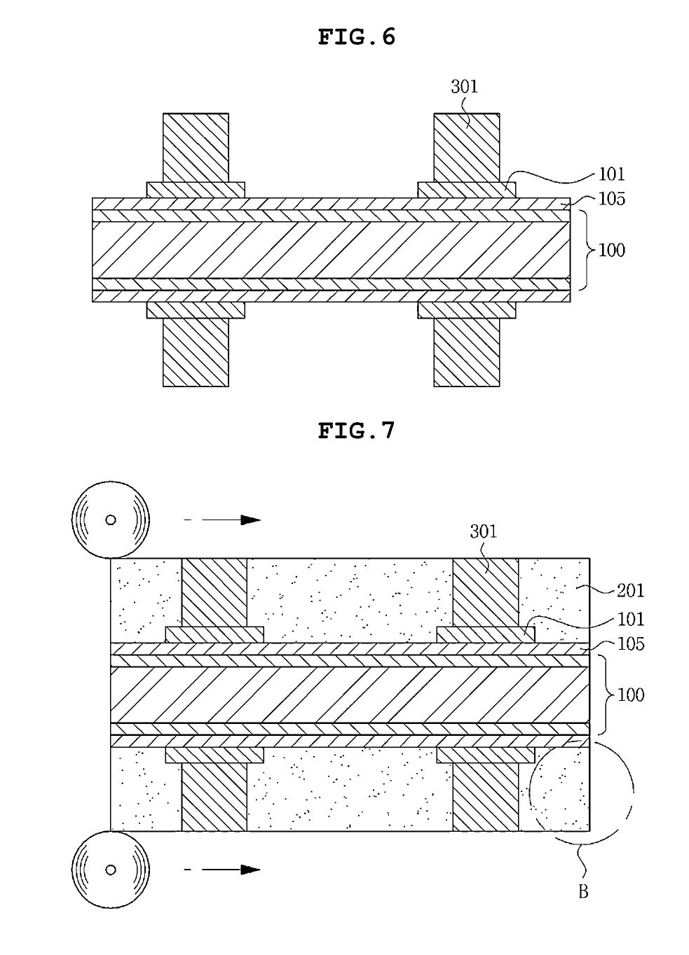

As shown in FIG. 6, the resist 401 is removed.

As shown in FIG. 7, a first insulating layer 201 may be formed on the carrier substrate 100 so as to enclose the first circuit layer 101 and the first via 301.

Here, a polishing process may be performed so that the first via 301 is exposed.

As the insulating layer, a resin insulating layer may be used. As the insulating layer, a thermosetting resin such as an epoxy resin, a thermoplastic resin such as polyimide, or a resin having a reinforcing material such as a glass fiber or an inorganic filler impregnated thereinto, for example, a prepreg, may be used.

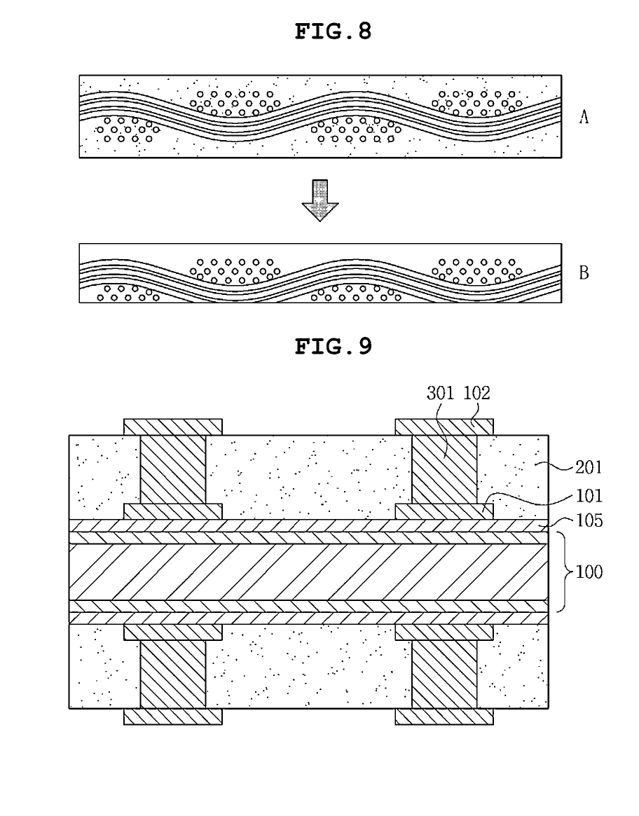

FIG. 8 shows enlarged structures of a B part in FIG. 7, obtained before and after performing the polishing process, respectively.

In the structure of the B part in FIG. 7, obtained before performing the polishing process, the entire glass cloth is positioned at the center of the insulating layer A, but after performing the polishing process, the insulating layer B may have a structure in which a portion of the glass cloth that is polished is removed.

As shown in FIG. 9, a second circuit layer 102 may be formed on the polished insulating layer 201.

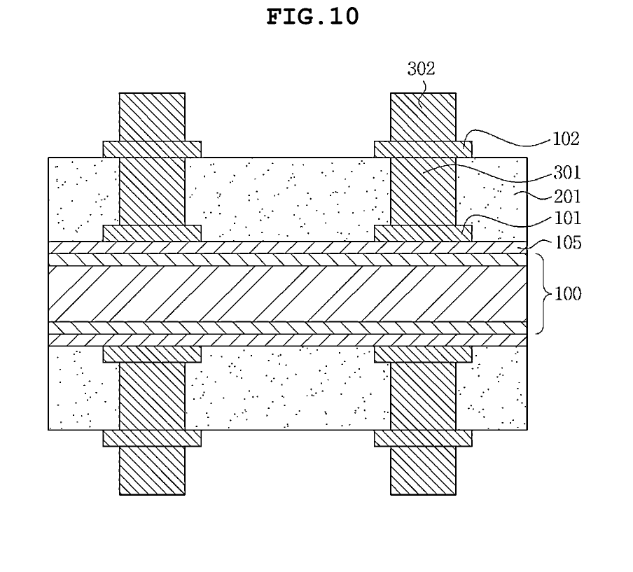

As shown in FIG. 10, a second via 302 may be formed on the second circuit layer 102.

Here, since a method of forming the via is the same as the above-description, the overlapped description will be omitted.

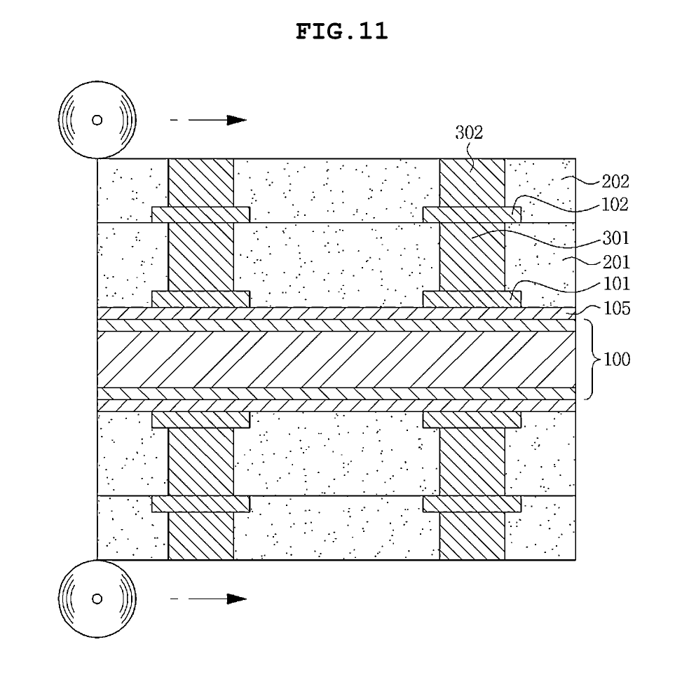

As shown in FIG. 11, a second insulating layer 202 may be formed so as to enclose the second circuit layer 102 and the second via 302.

Here, the polishing process may be performed so that the second via 302 is exposed.

A thickness to be polished may be formed so that shrinkage stresses operated on the polished first insulating layer 201 and the polished second insulating layer 202 have an opposite direction.

In addition, the thickness of the second insulating layer 202 may be controlled through the polishing process so that the second insulating layer 202 has a smile warpage.

Here, a thickness ratio between the first and second insulating layers may be as follows: 0.22<Thickness of Second Insulating Layer/Thickness of First Insulating Layer≦1.0.

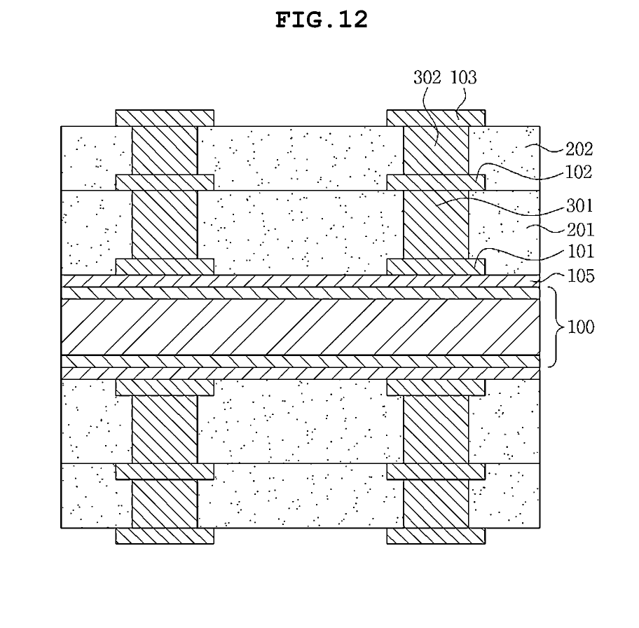

As shown in FIG. 12, a third circuit layer 103 may be further formed on the polished second insulating layer 202, and although not shown, the build-up layer may be further formed.

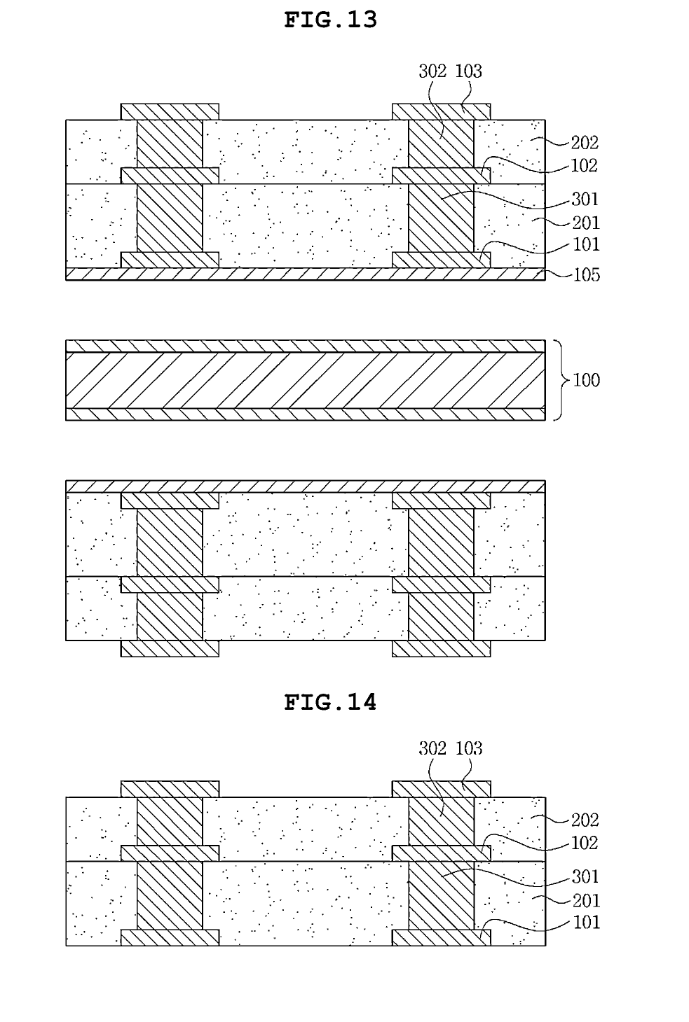

As shown in FIG. 13, the carrier substrate 100 and the first insulating layer 201 may be separated from each other.

As shown in FIG. 14, the protective film 105 may be removed from a lower surface of the separated first insulating layer 201.

The printed circuit board according to the preferred embodiment of the present invention may have different thicknesses of the insulating layers by performing the polishing process, making it possible to prevent the warpage.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
a plurality of circuit layers; and
a plurality of insulating layers interposed between the plurality of circuit layers,
wherein two adjacent insulating layers of the plurality of insulating layers have different thicknesses.

2. The printed circuit board as set forth in claim 1, wherein two adjacent insulating layers have a glass cloth.

3. The printed circuit board as set forth in claim 1, further comprising: vias electrically connecting between the plurality of circuit layers while penetrating through the insulating layers.

4. A method of manufacturing a printed circuit board, the method comprising:
preparing a carrier substrate;
forming first circuit layers on both surfaces of the carrier substrate;
forming a first via on the first circuit layer;
forming a first insulating layer so as to enclose the first circuit layer and the first via;
polishing the first insulating layer;
forming a second circuit layer at a position corresponding to the first via;
forming a second via on the second circuit layer;
forming a second insulating layer so as to enclose the second circuit layer and the second via;
polishing the second insulating layer so as to have a thickness thinner than that of the first insulating layer; and
separating the first insulating layer from the carrier substrate.

5. The method as set forth in claim 4, wherein the forming of the first via includes:
forming a resist on the first circuit layer, the resist having an opening part at a position corresponding to the first via;
filling the opening part with a metal to form the first via; and
removing the resist.

6. The method as set forth in claim 4, wherein the forming of the second via includes:
forming a resist on the second circuit layer, the resist having an opening part at a position corresponding to the second via;
filling the opening part with a metal to form the second via; and
removing the resist.

7. The method as set forth in claim 4, further comprising: forming a third circuit layer at a position corresponding to the second via after the polishing of the second insulating layer.

8. The method as set forth in claim 4, further comprising:
attaching a protective film onto the carrier substrate in the preparing of the carrier substrate; and
removing the protective film after the separating of the first insulating layer from the carrier substrate.

9. The method as set forth in claim 4, wherein the first and second insulating layers have a glass cloth.

10. The method as set forth in claim 4, wherein the glass cloth of first and second insulating layers is partially polished in the polishing of the first insulating layer and the second insulating layer.
